(19) United States
(12) Patent Application Publication
(10) Pub. No.: US 2010/0127382 A1
(43) Pub. Date: May 27, 2010

(54) SEMICONDUCTOR DEVICE

(76) Inventors: Toshitaka AKAHOSHI, Shiga (JP); Teppei IWASE, Hyogo (JP); Yoshiaki TAKEOKA, Kyoto (JP)

Correspondence Address: MCDERMOTT WILL & EMERY LLP, 600 13TH STREET, NW, WASHINGTON, DC, 20005-3096, US

(21) Appl. No.: 12/566,165

(22) Filed: Sep. 24, 2009

(30) Foreign Application Priority Data
Nov. 21, 2008 (JP) 2008-297617
Aug. 20, 2009 (JP) 2009-191269

(51) Int. Cl. H01L 23/48; H01L 23/482

(52) U.S. Cl. 257/692; 257/737; 257/E23.014; 257/E23.01

(57) ABSTRACT

A semiconductor device includes: a semiconductor carrier with a top surface on which a plurality of electrodes are disposed; and a semiconductor element electrically connected through a plurality of bump electrodes to the plurality of associated electrodes. The plurality of electrodes are substantially uniformly spaced.

### CROSS-REFERENCE TO RELATED APPLICATIONS

This application claims priority to Japanese Patent Application No. 2008-297617 filed on Nov. 21, 2008 and Japanese Patent Application No. 2009-191269 filed on Aug. 20, 2009, the disclosure of which including the specification, the drawings, and the claims is hereby incorporated by reference in its entirety.

### BACKGROUND

The present disclosure relates to semiconductor devices each configured such that a semiconductor element is bonded to a semiconductor carrier using flip-chip technology.

With size and weight reductions of portable information devices, etc., there are demands for higher-density, smaller, and thinner semiconductor devices. In order to meet these demands, semiconductor devices using flip-chip attachment have been developed.

For a known semiconductor device, in order to achieve a small semiconductor device, a method has been used wherein a semiconductor element is mounted to a semiconductor carrier with resin encapsulation material interposed therebetween by using a thermal press technique as described in, for example, Japanese Unexamined Patent Application Publication No. 2000-195879.

FIG. 7 is a cross-sectional view illustrating the structure of a known semiconductor device. As illustrated in FIG. 7, a semiconductor element 101 is electrically connected through a plurality of conductive bump electrodes 102 to a plurality of electrodes 104 disposed on the top surface of a semiconductor carrier 106. A space between the semiconductor element 101 and the semiconductor carrier 106 is filled with an insulative resin 103. A plurality of external electrodes 107 are disposed on the bottom surface of the semiconductor carrier 106.

### SUMMARY

However, in the above-mentioned known semiconductor device, joint failures may be caused between the semiconductor element 101 and the semiconductor carrier 106.

In view of the above, an object of the present disclosure is to provide a semiconductor device which is configured such that a semiconductor element is bonded to a semiconductor carrier using flip-chip technology and which prevents joint failures between the semiconductor element and the semiconductor carrier and thereby improves the mounting reliability.

In order to achieve the above-described object, the present inventors studied causes of joint failures between the semiconductor element 101 and semiconductor carrier 106 of the above-described known semiconductor device in various ways. This study proved that such problems as illustrated in FIGS. 8A and 8B arose from the fact that some of the spacing pitches between adjacent ones of the electrodes 104 disposed on the top surface of the semiconductor carrier 106 are larger than the other ones thereof.

More specifically, first, when the semiconductor element 101 is bonded to the semiconductor carrier 106 as illustrated in FIG. 8A, the temperature of the semiconductor carrier 106 is increased to the vicinity of the glass transition temperature. Therefore, the semiconductor carrier 106 is softened. As a result, the semiconductor element 101 sinks down. Meanwhile, in a region of the semiconductor device where the intervals between adjacent ones of the associated electrodes 104 are relatively large, a resin (carrier resin) forming the semiconductor carrier 106 is softened so as to be partially squeezed out by a pressure from the semiconductor element 101, thereby forming a projection 111. Subsequently, after the electrodes 104 on the semiconductor carrier 106 are bonded to bump electrodes 102 on the semiconductor element 101, the pressure applied to the semiconductor carrier 106 is released, and the temperature of the semiconductor carrier 106 is decreased as illustrated in FIG. 8B. This eliminates the sinking of the semiconductor element 101. Meanwhile, the projection 111 of the carrier resin shrinks, thereby causing a stress pulling the insulative resin 103 toward the semiconductor carrier 106. As a result, a separation 112 occurs at the interface between the semiconductor element 101 and the insulative resin 103. This causes joint failures between the semiconductor element 101 and the semiconductor carrier 106. In particular, when the semiconductor element 101 is made of an inorganic material, and the insulative resin 103 is made of an organic material, the adhesion between the semiconductor element 101 and the insulative resin 103 is reduced. Therefore, the separation 112 becomes more likely to occur. Consequently, joint failures become more likely to be caused between the semiconductor element 101 and the semiconductor carrier 106.

The present disclosure has been made in view of the above-mentioned knowledge. A semiconductor device according to a first aspect of the present disclosure includes: a semiconductor carrier with a top surface on which a plurality of electrodes are disposed; and a semiconductor element electrically connected through a plurality of bump electrodes to the plurality of associated electrodes. The plurality of electrodes are substantially uniformly spaced. Here, the phrase “substantially uniformly” means that minor dimension errors, etc., may be caused due to process variations or any other cause.

According to the semiconductor device of the first aspect of the present disclosure, the electrodes are uniformly spaced on the top surface of the semiconductor carrier. Therefore, when the semiconductor element is bonded to the semiconductor carrier by using a thermal press technique, the pressure applied from the semiconductor element to the semiconductor carrier can be evenly spread. For this reason, a projection of the softened carrier resin becomes less likely to be formed between an adjacent pair of the electrodes. In view of the above, when the electrodes on the semiconductor carrier are bonded to the bump electrodes on the semiconductor element, the pressure applied to the semiconductor carrier is then released, and the temperature of the semiconductor carrier is decreased; joint failures between the semiconductor element and the semiconductor carrier can be prevented from being caused due to the shrinkage of the projection of the carrier resin, resulting in improved mounting reliability of the semiconductor device. In particular, when a space between the semiconductor element and the semiconductor carrier is filled with an insulative resin, a stress pulling the insulative resin toward the semiconductor carrier can be prevented from being caused due to the shrinkage of the projection of the carrier resin. This can prevent a separation at the interface between the semiconductor element and the insulative resin, resulting in improved mounting reliability of the semiconductor device.

In the semiconductor device according to the first aspect of the present disclosure, the plurality of electrodes may include a first electrode having a first width, and a second electrode having a second width greater than the first width. More specifically, when the spacing pitches between adjacent ones of some of the disposed electrodes on the top surface of the semiconductor carrier are nonuniform, the widths of the electrodes may be changed so that the intervals between adjacent ones of the electrodes become equal. In this case, a middle of the second electrode may be separated from a middle of one of the plurality of bump electrodes connected to the second electrode. Alternatively, the middle of the second electrode may coincide with the middle of one of the plurality of bump electrodes connected to the second electrode. To be specific, when the plurality of electrodes are successively arranged at different pitches, middles of the outermost ones of the plurality of electrodes may be separated from middles of the associated bump electrodes, and middles of the other electrodes may coincide with middles of the associated bump electrodes.

A semiconductor device according to a second aspect of the present disclosure includes: a semiconductor carrier with a top surface on which a plurality of electrodes are disposed; and a semiconductor element electrically connected through a plurality of bump electrodes to the plurality of associated electrodes. The spacing intervals between adjacent ones of the plurality of electrodes include a first spacing interval and a second spacing interval greater than the first spacing interval, and a dummy electrode is disposed on the top surface of the semiconductor carrier and between an adjacent pair of the plurality of electrodes spaced at the second spacing interval.

According to the semiconductor device of the second aspect of the present disclosure, the dummy electrode is disposed on the top surface of the semiconductor carrier and between an adjacent pair of the electrodes spaced at the second spacing interval (relatively large interval). Therefore, when the semiconductor element is bonded to the semiconductor carrier by using a thermal press technique, provision of the dummy electrode can restrain the softened carrier resin from projecting between the adjacent pair of the electrodes. In view of the above, when the electrodes on the semiconductor carrier are bonded to the bump electrodes on the semiconductor element, the pressure applied to the semiconductor carrier is then released, and the temperature of the semiconductor carrier is decreased; joint failures between the semiconductor element and the semiconductor carrier can be prevented from being caused due to the shrinkage of the projection of the carrier resin, resulting in improved mounting reliability of the semiconductor device. In particular, when a space between the semiconductor element and the semiconductor carrier is filled with an insulative resin, a stress pulling the insulative resin toward the semiconductor carrier can be prevented from being caused. This can prevent a separation at the interface between the semiconductor element and the insulative resin, resulting in improved mounting reliability of the semiconductor device.

In the semiconductor device according to the second aspect of the present disclosure, the plurality of electrodes and the dummy electrode may be uniformly spaced. More specifically, when the spacing pitches between adjacent ones of some of the electrodes on the top surface of the semiconductor carrier are nonuniform, the dummy electrode may be disposed so that the intervals between adjacent ones of the electrodes become equal. Thus, when the semiconductor element is bonded to the semiconductor carrier by using a thermal press technique, the pressure applied from the semiconductor element to the semiconductor carrier can be evenly spread. For this reason, a projection of the softened carrier resin becomes less likely to be formed between an adjacent pair of the electrodes, resulting in further improved mounting reliability of the semiconductor device.

In the semiconductor device according to the second aspect of the present disclosure, middles of the plurality of electrodes may coincide with middles of the plurality of associated bump electrodes.

A semiconductor device according to a third aspect of the present disclosure includes: a semiconductor carrier with a top surface on which a plurality of electrodes are disposed; and a semiconductor element electrically connected through a plurality of bump electrodes to the plurality of associated electrodes. A conductive pattern is buried in a part of the semiconductor carrier located under at least one of the plurality of electrodes.

According to the semiconductor device of the third aspect of the present disclosure, the conductive pattern is buried in a part of the semiconductor carrier located under at least one of the plurality of electrodes. Therefore, when the semiconductor element is bonded to the semiconductor carrier by using a thermal press technique, provision of the conductive pattern can prevent the electrodes from sinking into the softened carrier resin. For this reason, a projection of the softened carrier resin becomes less likely to be formed between an adjacent pair of the electrodes. In view of the above, when the electrodes on the semiconductor carrier are bonded to the bump electrodes on the semiconductor element, the pressure applied to the semiconductor carrier is then released, and the temperature of the semiconductor carrier is decreased; joint failures between the semiconductor element and the semiconductor carrier can be prevented from being caused due to the shrinkage of the projection of the carrier resin, resulting in improved mounting reliability of the semiconductor device. In particular, when a space between the semiconductor element and the semiconductor carrier is filled with an insulative resin, a stress pulling the insulative resin toward the semiconductor carrier can be prevented from being caused due to the shrinkage of the projection of the carrier resin. This can prevent a separation at the interface between the semiconductor element and the insulative resin, resulting in improved mounting reliability of the semiconductor device.

In the semiconductor device according to the third aspect of the present disclosure, a conductive pattern may be buried in a part of the semiconductor carrier located between at least one adjacent pair of the plurality of electrodes. In this case, when the semiconductor element is bonded to the semiconductor carrier by using a thermal press technique, provision of the conductive pattern can prevent the softened carrier resin from projecting between the adjacent pair of the electrodes. This results in further improved mounting reliability of the semiconductor device.

A semiconductor device according to a fourth aspect of the present disclosure includes: a semiconductor carrier with a top surface on which a plurality of electrodes are disposed; and a semiconductor element electrically connected through a plurality of bump electrodes to the plurality of associated electrodes. A conductive pattern is buried in a part of the semiconductor carrier located between at least one adjacent pair of the plurality of electrodes.

According to the semiconductor device of the fourth aspect of the present disclosure, the conductive pattern is buried in a part of the semiconductor carrier located between at least one adjacent pair of the plurality of electrodes. Therefore, when a semiconductor element is bonded to the semiconductor carrier by using a thermal press technique, provision of the conductive pattern can restrain the softened carrier resin from projecting between the adjacent pair of the electrodes. In view of the above, when the electrodes on the semiconductor carrier are bonded to the bump electrodes on the semiconductor element, the pressure applied to the semiconductor carrier is then released, and the temperature of the semiconductor carrier is decreased; joint failures between the semiconductor element and the semiconductor carrier can be prevented from being caused due to the shrinkage of the projection of the carrier resin, resulting in improved mounting reliability of the semiconductor device. In particular, when a space between the semiconductor element and the semiconductor carrier is filled with an insulative resin, a stress pulling the insulative resin toward the semiconductor carrier can be prevented from being caused due to the shrinkage of the projection of the carrier resin. This can prevent a separation at the interface between the semiconductor element and the insulative resin, resulting in improved mounting reliability of the semiconductor device.

In the semiconductor device according to the fourth aspect of the present disclosure, an interval between the adjacent pair of the plurality of electrodes may be greater than each of intervals between the other adjacent pairs of the plurality of electrodes. Thus, the conductive pattern is buried in a wide part of the semiconductor carrier which is located between the adjacent pair of the plurality of electrodes and from which the carrier resin is more likely to project. This can effectively restrain the projection of the carrier resin, resulting in further improved mounting reliability of the semiconductor device.

In the semiconductor device according to the third or fourth aspect of the present disclosure, the conductive pattern may be buried in a part of the semiconductor carrier located under the semiconductor element. More specifically, when the conductive pattern is buried in a part of the semiconductor carrier which is located under the semiconductor element and to which a large pressure is applied from above, the above-mentioned advantages are more noticeably provided.

In the semiconductor device according to the third or fourth aspect of the present disclosure, multi-level conductive patterns may be disposed in the semiconductor carrier. In this case, the width of each of upper ones of the conductive patterns may be greater than that of each of lower ones of the conductive patterns.

In the semiconductor device according to any one of the first through fourth aspects of the present disclosure, the semiconductor element may be mounted face-down on the top surface of the semiconductor carrier, and may be covered with a resin. More specifically, for a resin-molded semiconductor device the amount of warpage of which is large and which is more likely to induce separation, particularly, for a semiconductor device molded of a thermosetting resin, the present disclosure is particularly advantageous.

In the semiconductor device of any one of the first through fourth aspects of the present disclosure, a space between the semiconductor element and the semiconductor carrier may be filled with an insulative resin. Thus, the above-mentioned advantages are more noticeably provided than in the known art.

In the semiconductor device of any one of the first through fourth aspect of the present disclosure, the plurality of electrodes may be arranged at least two different pitches. This can increase the degree of flexibility in arranging the plurality of electrodes on the semiconductor carrier, and allows, for example, the capacitance of an electrostatic discharge (ESD) protection circuit for an analog circuit, etc., to greatly vary. This capacitance variation can improve resistance to a surge breakdown.

As described above, according to the present disclosure, the projection of the carrier resin can be prevented from being caused when the semiconductor element is bonded to the semiconductor carrier. This can prevent joint failures between the semiconductor element and the semiconductor carrier from being caused due to the subsequent shrinkage of the projection of the carrier resin, resulting in improved mounting reliability of the semiconductor device.

In other words, the semiconductor device of the present disclosure can prevent joint failures between the semiconductor element and the semiconductor carrier, resulting in improved mounting reliability of the semiconductor device. The semiconductor device is advantageously applied to data communication equipment, office electronic equipment, household electronic appliances, industrial electronic equipment, such as measurement devices or assembly robots, medical electronic equipment, electronic toys, or any other equipment.

### BRIEF DESCRIPTION OF THE DRAWINGS

FIG. 1 is a cross-sectional view illustrating the structure of a semiconductor device according to a first embodiment of the present disclosure.

FIGS. 2A through 2D are cross-sectional views illustrating process steps in a method for fabricating a semiconductor device according to the first embodiment of the present disclosure.

FIG. 3 is a cross-sectional view illustrating the structure of a semiconductor device according to a second embodiment of the present disclosure.

FIGS. 4A through 4D are cross-sectional views illustrating process steps in a method for fabricating a semiconductor device according to the second embodiment of the present disclosure.

FIG. 5 is a cross-sectional view illustrating the structure of a semiconductor device according to a third embodiment of the present disclosure.

FIGS. 6A through 6D are cross-sectional views illustrating process steps in a method for fabricating a semiconductor device according to the third embodiment of the present disclosure.

FIG. 7 is a cross-sectional view illustrating the structure of a known semiconductor device.

FIGS. 8A and 8B are cross-sectional views of the known semiconductor device for explaining problems related to the known semiconductor device.

FIG. 9 is a cross-sectional view illustrating the structure of a semiconductor device according to a modification of the first embodiment of the present disclosure.

### DETAILED DESCRIPTION

### Embodiment 1

A semiconductor device according to a first embodiment of the present disclosure, more specifically, a semiconductor device configured such that a semiconductor element is bonded to a semiconductor carrier using flip-chip technology, and a method for fabricating the same will be described hereinafter with reference to the drawings.

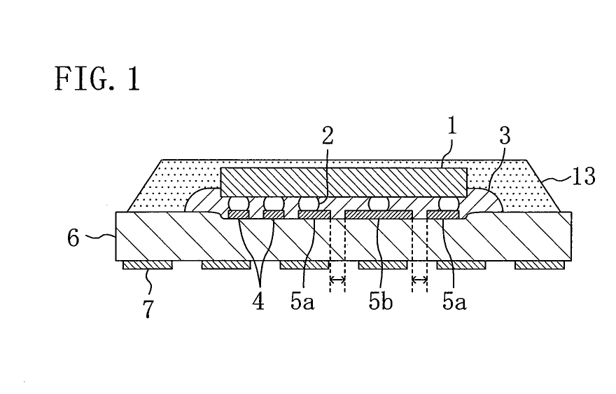

FIG. 1 is a cross-sectional view illustrating the structure of the semiconductor device according to the first embodiment of the present disclosure. As illustrated in FIG. 1, a semiconductor element 1 is electrically connected through a plurality of conductive bump electrodes 2 to a plurality of electrodes 4, 5a, and 5b disposed on the top surface of a semiconductor carrier 6. A space between the semiconductor element 1 and the semiconductor carrier 6 is filled with an insulative resin 3. The semiconductor element 1 is mounted face-down on the top surface of the semiconductor carrier 6, and is covered with an insulative resin 13, e.g., a thermosetting resin. A plurality of external electrodes 7 are disposed on the bottom surface of the semiconductor carrier 6. For example, solder balls, balls made of a metal other than solder, or lands or bumps that do not have ball shapes may be formed as the external electrodes 7.

One of the features of this embodiment is that the electrodes 4, 5a, and 5b are uniformly spaced on the top surface of the semiconductor carrier 6. Here, the phrase “the spacing intervals between adjacent ones of the electrodes” means the distances between the opposed lateral ends of adjacent ones of the electrodes, and the phrase “the spacing pitches between adjacent ones of the electrodes” means the distances between the middles of adjacent ones of the electrodes. More specifically, the intervals between adjacent ones of the electrodes 5a and 5b arranged at a pitch different from the pitch between an adjacent pair of the electrodes 4 (pitch larger than the pitch between the adjacent pair of the electrodes 4) are made equal by changing (increasing) the widths of the electrodes 5a and 5b. For example, when the plurality of electrodes 5a and 5b (each having the same width as each electrode 4) are arranged successively at a pitch larger than the pitch between an adjacent pair of the electrodes 4 in the design phase, the intervals between adjacent ones of the electrodes 5a and 5b are set equal to the intervals between the electrodes 4 in the following manner: the width of each of the outermost ones 5a of the electrodes 5a and 5b is extended toward the adjacent electrode 5b, and the width of the other electrode 5b is extended in both lateral directions. The pitch between the electrode 5b and each of the adjacent electrodes 5a is relatively large. In the above-mentioned case, the middles of the electrodes 5a are separated from the middles of the associated bump electrodes 2, and the middle of the electrode 5b coincides with the middle of the associated bump electrode 2.

According to this embodiment, the electrodes 4, 5a, and 5b are uniformly spaced on the top surface of the semiconductor carrier 6. Therefore, when the semiconductor element 1 is bonded to the semiconductor carrier 6 by using a thermal press technique, a pressure applied from the semiconductor element 1 to the semiconductor carrier 6 can be evenly spread. For this reason, a projection of the softened carrier resin becomes less likely to be caused between an adjacent pair of the electrodes. In view of the above, when the electrodes 4, 5a, and 5b on the semiconductor carrier 6 are bonded to the bump electrodes 2 on the semiconductor element 1, the pressure applied to the semiconductor carrier 6 is then released, and the temperature of the semiconductor carrier 6 is decreased; a stress pulling the insulative resin 3 toward the semiconductor carrier 6 can be prevented from being caused due to the shrinkage of the projection of the carrier resin. This can prevent a separation at the interface between the semiconductor element 1 and the insulative resin 3, resulting in improved mounting reliability of the semiconductor device.

In this embodiment, a material whose deformation magnitude is small when the semiconductor element 1 is bonded to the material by using a thermal press technique is desired as the material of the semiconductor carrier 6. Preferable materials of the semiconductor carrier 6 include, for example, a multi-layer ceramic substrate, a glass-cloth epoxy laminate (glass epoxy substrate), an aramid nonwoven fabric, and a glass-cloth polyimide resin laminate.

In this embodiment, Au stud bumps to which a wire bonding technique is applied are generally formed as the bump electrodes 2 used for the thermal press technique. Alternatively, bumps made of a metal other than Au, or balls or lands other than bumps may be formed. Furthermore, formation methods for bumps may include other methods, such as a plating method, a printing method, or a micro ball placement method.

In this embodiment, for example, a resin sheet may be used as the insulative resin 3 with which the space between the semiconductor element 1 and the semiconductor carrier 6 is filled. Here, the resin sheet may contain inorganic filler material, such as silica. Alternatively, the resin sheet may contain no inorganic filler material. The insulative resin 3 desirably has a thermal resistance high enough to resist high temperatures in a later reflow process (e.g., a thermal resistance high enough to resist a temperature of 240° C. for ten seconds). Preferable resin sheets include, for example, an epoxy resin, a phenolic resin, or a polyimide.

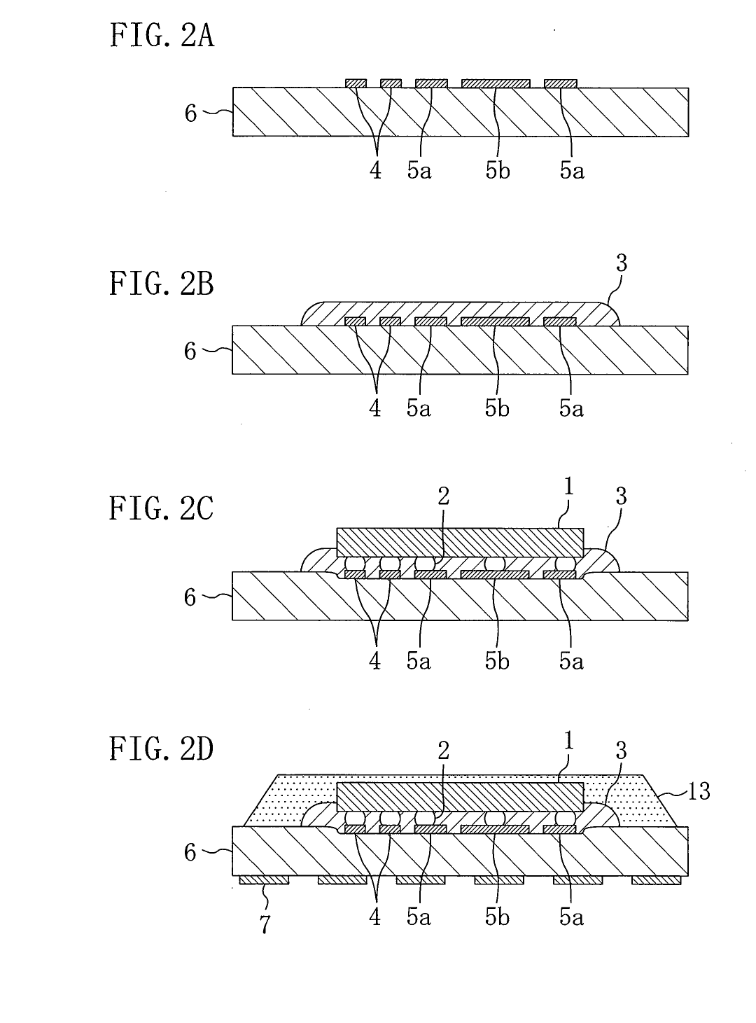

FIGS. 2A through 2D are cross-sectional views illustrating process steps in the fabrication method for a semiconductor device according to the first embodiment of the present disclosure. Referring to FIGS. 2A through 2D, the same components as those of the semiconductor device of this embodiment illustrated in FIG. 1 are labeled with the same reference characters, and redundant discussion thereof is omitted.

First, as illustrated in FIG. 2A, a semiconductor carrier 6 is prepared. A plurality of electrodes 4, 5a, and 5b are uniformly spaced on the top surface of the semiconductor carrier 6 (but not arranged at a fixed pitch). Then, as illustrated in FIG. 2B, a resin sheet forming an insulative resin 3 is disposed on the top surface of the semiconductor carrier 6 to cover the electrodes 4, 5a, and 5b.

Subsequently, as illustrated in FIG. 2C, a semiconductor element 1 is electrically connected through a plurality of conductive bump electrodes 2 to the electrodes 4, 5a, and 5b disposed on the top surface of the semiconductor carrier 6 so that the bump electrodes 2 break through the resin sheet forming the insulative resin 3. Thereafter, as illustrated in FIG. 2D, the semiconductor element 1 mounted face-down on the top surface of the semiconductor carrier 6 is covered with an insulative resin 13, e.g., a thermosetting resin, and a plurality of external electrodes 7 are formed on the bottom surface of the semiconductor carrier 6.

In this embodiment, before the electrodes 4, 5a, and 5b are connected to the bump electrodes 2 in the process step illustrated in FIG. 2C, the electrodes 4, 5a, and 5b are covered with the resin sheet forming the insulative resin 3 in the process step illustrated in FIG. 2B. Alternatively, the process step illustrated in FIG. 2B may be omitted. In this case, in the process step illustrated in FIG. 2D, a space between the semiconductor element 1 and the semiconductor carrier 6 may be filled with the insulative resin 13.

(Modification of Embodiment 1)

A semiconductor device according to a modification of the first embodiment of the present disclosure, more specifically, a semiconductor device configured such that a semiconductor element is bonded to a semiconductor carrier using flip-chip technology, and a fabrication method for the same will be described hereinafter with reference to the drawings.

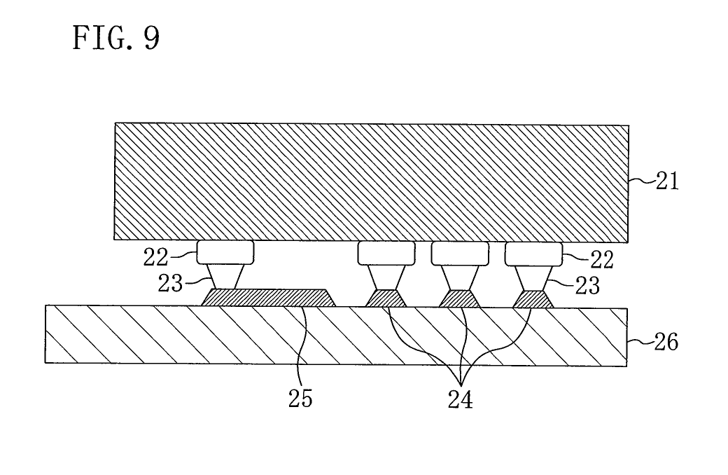

FIG. 9 is a cross-sectional view illustrating the structure of the semiconductor device according to the modification of the first embodiment of the present disclosure. As illustrated in FIG. 9, a plurality of electrodes, more specifically, electrodes 24, and an electrode 25 that is wider than each of the electrodes 24, are provided on the top surface of a semiconductor carrier 26. Furthermore, a plurality of electrode pads 22 having equal widths are provided on a semiconductor element 21. The electrodes 24 and 25 on the semiconductor carrier 26 are electrically connected through a plurality of conductive bump electrodes 23 to the electrode pads 22 on the semiconductor element 21. Here, the semiconductor element 21 is mounted face-down on the top surface of the semiconductor carrier 26.

Although not illustrated, the semiconductor element 21 may be covered with an insulative resin. Furthermore, a plurality of external electrodes may be disposed on the bottom surface of the semiconductor carrier 26.

Also in this modification, like the first embodiment, the electrodes 24 and 25 are uniformly spaced on the top surface of the semiconductor carrier 26. Here, the spacing pitch between the electrode 25 and the adjacent electrode 24 is larger than that between an adjacent pair of the electrodes 24. In other words, the electrodes 24 and 25 are arranged at two different pitches. Likewise, the electrode pads 22 or bump electrodes 23 on the semiconductor element 21 are also arranged at two different pitches.

According to this modification, not only the same advantages as in the first embodiment, but also the following advantage can be achieved. More specifically, since the plurality of electrodes 24 and 25 are arranged on the top surface of the semiconductor carrier 26 at different pitches, this can increase the degree of flexibility in arranging the plurality of electrodes 24 and 25, and allows, for example, the capacitance of an ESD protection circuit for an analog circuit, etc., to greatly vary. This capacitance variation can improve resistance to a surge breakdown.

In this modification, the plurality of electrodes 24 and 25 on the semiconductor carrier 26 (or the plurality of electrode pads 22 or bump electrodes 23 on the semiconductor element 21) are arranged at two different pitches. It will be obvious that the electrodes 24 and 25, the electrode pads 22, or the bump electrodes 23 may alternatively be arranged at three or more different pitches.

Furthermore, in this modification, a material similar to the material of the semiconductor carrier 6 in the first embodiment may be used as a material of the semiconductor carrier 26. Moreover, bumps, etc., similar to the bump electrodes 2 in the first embodiment may be formed as the bump electrodes 23.

### Embodiment 2

A semiconductor device according to a second embodiment of the present disclosure, more specifically, a semiconductor device configured such that a semiconductor element is bonded to a semiconductor carrier using flip-chip technology, and a fabrication method for the same will be described hereinafter with reference to the drawings.

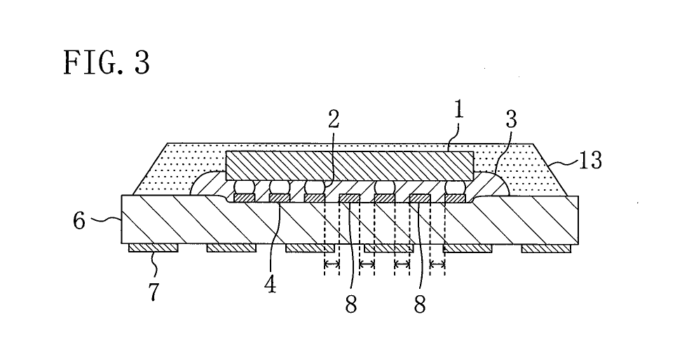

FIG. 3 is a cross-sectional view illustrating the structure of the semiconductor device according to the second embodiment of the present disclosure. Referring to FIG. 3, the same components as those of the semiconductor device of the first embodiment illustrated in FIG. 1 are labeled with the same reference characters, and redundant discussion thereof is omitted.

In this embodiment, a plurality of electrodes 4 having equal widths are disposed on the top surface of a semiconductor carrier 6. Here, the spacing intervals between adjacent ones of the plurality of electrodes 4 include a relatively small interval (first spacing interval) and a relatively large interval (second spacing interval). In other words, the plurality of electrodes 4 are arranged at a plurality of different pitches.

One of the features of this embodiment is that dummy electrodes 8 formed of, for example, metal patterns (dummy electrodes that are not bonded to bump electrodes 2) are disposed on the top surface of the semiconductor carrier 6 and between adjacent ones of some of the electrodes 4 spaced at relatively large intervals (second spacing intervals) as illustrated in FIG. 3. More specifically, the dummy electrodes 8 are disposed on the top surface of the semiconductor carrier 6 and between adjacent ones of some of the electrodes 4 nonuniformly spaced (at a larger spacing pitch). Thus, the intervals between the dummy electrodes 8 and the adjacent electrodes 4 are set equal to the intervals between adjacent ones of the other electrodes 4. Here, the middles of the electrodes 4 may coincide with the middles of the corresponding bump electrodes 2.

According to this embodiment, the dummy electrodes 8 are disposed on the top surface of the semiconductor carrier 6 and between adjacent ones of some of the electrodes 4 spaced at relatively large intervals. Therefore, when a semiconductor element 1 is bonded to the semiconductor carrier 6 by using a thermal press technique, provision of the dummy electrodes 8 can restrain the softened carrier resin from projecting between adjacent ones of the electrodes 4. In view of the above, when the electrodes 4 on the semiconductor carrier 6 are bonded to the bump electrodes 2 on the semiconductor element 1, the pressure applied to the semiconductor carrier 6 is then released, and the temperature of the semiconductor carrier 6 is decreased; a stress pulling an insulative resin 3 toward the semiconductor carrier 6 can be prevented from being caused due to the shrinkage of a projection of the carrier resin. This can prevent a separation at the interface between the semiconductor element 1 and the insulative resin 3, resulting in improved mounting reliability of the semiconductor device.

In particular, in this embodiment, the dummy electrodes 8 and the electrodes 4 are uniformly spaced. Therefore, when the semiconductor element 1 is bonded to the semiconductor carrier 6 by using a thermal press technique, the pressure applied from the semiconductor element 1 to the semiconductor carrier 6 can be evenly spread. For this reason, the projection of the softened carrier resin becomes less likely to be formed between an adjacent pair of the electrodes. However, the dummy electrodes 8 and the electrodes 4 do not necessarily need to be uniformly spaced.

In this embodiment, the widths of the electrodes 4 are preferably set equal to one another. This applies also to some of the electrodes 4 arranged at a spacing pitch different from (larger than) the other electrodes 4. This setting prevents an undesired capacitance from being added to the electrodes 4 also when the electrodes 4 are, for example, signal terminals. Therefore, the characteristic impedance does not partially vary. This can provide good signal integrity. However, the widths of the electrodes 4 do not necessarily need to be set equal to one another.

Furthermore, in this embodiment, the dummy electrodes 8 disposed between adjacent ones of some of the electrodes 4 are preferably set to a power or ground attribute. This can suppress the capacitance increase, and can reduce the electrical resistance. Therefore, good power integrity can be achieved.

Moreover, since, in this embodiment, the plurality of electrodes 4 are spaced on the top surface of the semiconductor carrier 6 at different pitches, this can increase the degree of flexibility in arranging the plurality of electrodes 4, and allows, for example, the capacitance of an ESD protection circuit for an analog circuit, etc., to greatly vary. This capacitance variation can improve resistance to a surge breakdown.

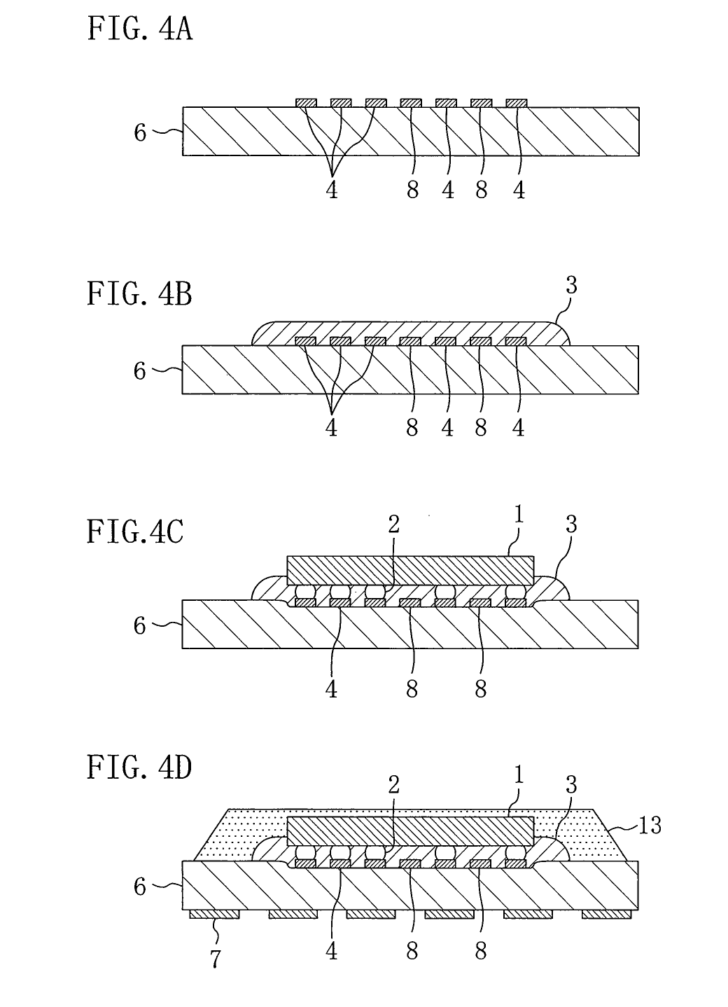

FIGS. 4A through 4D are cross-sectional views illustrating process steps in the fabrication method for a semiconductor device according to the second embodiment of the present disclosure. Referring to FIGS. 4A through 4D, the same components as those of the semiconductor device of this embodiment illustrated in FIG. 3 are labeled with the same reference characters, and redundant discussion thereof is omitted.

First, as illustrated in FIG. 4A, a semiconductor carrier 6 is prepared. A plurality of electrodes 4 and dummy electrodes 8 are uniformly spaced on the top surface of the semiconductor carrier 6. Then, as illustrated in FIG. 4B, a resin sheet forming an insulative resin 3 is disposed on the top surface of the semiconductor carrier 6 to cover the electrodes 4 and the dummy electrodes 8.

Subsequently, as illustrated in FIG. 4C, a semiconductor element 1 is electrically connected through a plurality of conductive bump electrodes 2 to the plurality of electrodes 4 disposed on the top surface of the semiconductor carrier 6 so that the bump electrodes 2 break through the resin sheet forming the insulative resin 3. Thereafter, as illustrated in FIG. 4D, the semiconductor element 1 mounted face-down on the top surface of the semiconductor carrier 6 is covered with an insulative resin 13, e.g., a thermosetting resin, and a plurality of external electrodes 7 are formed on the bottom surface of the semiconductor carrier 6.

In this embodiment, before the electrodes 4 are connected to the bump electrodes 2 in the process step illustrated in FIG. 4C, the electrodes 4 and the dummy electrodes 8 are covered with the resin sheet forming the insulative resin 3 in the process step illustrated in FIG. 4B. Alternatively, the process step illustrated in FIG. 4B may be omitted. In this case, a space between the semiconductor element 1 and the semiconductor carrier 6 may be filled with the insulative resin 13 in the process step illustrated in FIG. 4D.

### Embodiment 3

A semiconductor device according to a third embodiment of the present disclosure, more specifically, a semiconductor device configured such that a semiconductor element is bonded to a semiconductor carrier using flip-chip technology, and a fabrication method for the same will be described hereinafter with reference to the drawings.

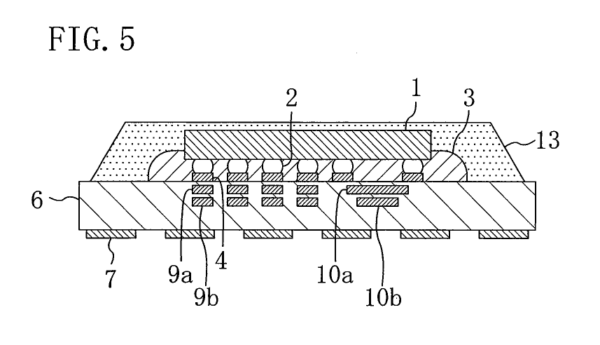

FIG. 5 is a cross-sectional view illustrating the structure of the semiconductor device according to the third embodiment of the present disclosure. Referring to FIG. 5, the same components as those of the semiconductor device of the first embodiment illustrated in FIG. 1 are labeled with the same reference characters, and redundant discussion thereof is omitted.

In this embodiment, a plurality of electrodes 4 having equal widths are disposed on the top surface of a semiconductor carrier 6. Here, the spacing intervals between adjacent ones of the plurality of electrodes 4 include a relatively small interval (first spacing interval) and a relatively large interval (second spacing interval). In other words, the plurality of electrodes 4 are arranged at a plurality of different pitches.

The features of this embodiment different from those of the first embodiment include the following: as illustrated in FIG. 5, conductive patterns 9a and 9b formed of, for example, metal patterns are buried in parts of the semiconductor carrier 6 located under the electrodes 4, and conductive patterns 10a and 10b formed of, for example, metal patterns are buried in a part of the semiconductor carrier 6 located between an adjacent pair of the electrodes 4. In this embodiment, the conductive patterns 9a, 9b, 10a, and 10b are buried in a part of the semiconductor carrier 6 located under the semiconductor element 1.

According to this embodiment, the conductive patterns 9a and 9b are buried in parts of the semiconductor carrier 6 located under the electrodes 4. Therefore, when the semiconductor element 1 is bonded to the semiconductor carrier 6 by using a thermal press technique, provision of the conductive patterns 9a and 9b can prevent the electrodes 4 from sinking into the softened carrier resin. For this reason, a projection of the softened carrier resin becomes less likely to be caused between an adjacent pair of the electrodes 4. Furthermore, the conductive patterns 10a and 10b are buried in a part of the semiconductor carrier 6 located between an adjacent pair of the electrodes 4. Therefore, when the semiconductor element 1 is bonded to the semiconductor carrier 6 by using a thermal press technique, provision of the conductive patterns 10a and 10b can restrain the softened carrier resin from projecting between the adjacent pair of the electrodes 4. In view of the above, when the electrodes 4 on the semiconductor carrier 6 are bonded to the bump electrodes 2 on the semiconductor element 1, the pressure applied to the semiconductor carrier 6 is then released, and the temperature of the semiconductor carrier 6 is decreased; a stress pulling the insulative resin 3 toward the semiconductor carrier 6 can be prevented from being caused due to the shrinkage of the projection of the carrier resin. This can prevent a separation at the interface between the semiconductor element 1 and the insulative resin 3, resulting in improved mounting reliability of the semiconductor device.

In this embodiment, the conductive patterns 9a and 9b located under the electrodes 4 are preferably buried in a part of the semiconductor carrier 6 located near the semiconductor element 1 (i.e., an upper part of the semiconductor carrier 6). Moreover, as in this embodiment, multi-level conductive patterns are preferably buried in parts of the semiconductor carrier 6 located under the electrodes 4. In this case, the width (area) of each of upper ones of multi-level conductive patterns (near the semiconductor element 1) is preferably greater than that (area) of each of lower ones of the multi-level conductive patterns (further from the semiconductor element 1).

Furthermore, in this embodiment, the conductive patterns 10a and 10b located in a part of the semiconductor carrier 6 between an adjacent pair of the electrodes 4 are also preferably buried in a part of the semiconductor carrier 6 located near the semiconductor element 1 (i.e., an upper part of the semiconductor carrier 6). Furthermore, as in this embodiment, multi-level conductive patterns are preferably buried in the part of the semiconductor carrier 6 located between the adjacent pair of the electrodes 4. In this case, the width (area) of each of upper ones of multi-level conductive patterns (near the semiconductor element 1) is preferably greater than that (area) of each of lower ones of the multi-level conductive patterns (further from the semiconductor element 1). In addition, lateral end parts of the conductive patterns 10a and 10b may overlap with the adjacent pair of the electrodes 4.

In this embodiment, the conductive patterns 9a and 9b are buried in parts of the semiconductor carrier 6 located under the electrodes 4, and the conductive patterns 10a and 10b are buried in a part of the semiconductor carrier 6 located between the adjacent pair of the electrodes 4. Alternatively, only either the conductive patterns 9a and 9b or the conductive patterns 10a and 10b may be provided.

In this embodiment, the conductive patterns 9a and 9b do not need to be disposed under all the electrodes 4. In this connection, only either the conductive patterns 9a or the conductive patterns 9b may be disposed under the electrodes 4. This also applies to the following description. When the conductive patterns 9a and 9b are disposed under at least one of the electrodes 4, this can provide the above-mentioned advantages. Similarly, the conductive patterns 10a and 10b do not need to be disposed in all of the parts of the semiconductor carrier 6 located between adjacent ones of all the electrodes 4. In this connection, only either the conductive patterns 10a or the conductive patterns 10b may be disposed therein. This also applies to the following description. When the conductive patterns 10a and 10b are disposed in a part of the semiconductor carrier 6 located between at least one adjacent pair of the electrodes 4, this can provide the above-mentioned advantages. In this case, when the width of the part of the semiconductor carrier 6 located between the at least one adjacent pair of the electrodes 4 and provided with the conductive patterns 10a and 10b is greater than that of each of parts of the semiconductor carrier 6 located between the other adjacent pairs of the electrodes 4, this can effectively suppress a projection of the carrier resin. The reason for this is that the conductive patterns 10a and 10b are buried in the wide part of the semiconductor carrier 6 which is located between the adjacent pair of the electrodes 4 and from which the carrier resin is more likely to project. The above-mentioned suppression can further improve the mounting reliability of the semiconductor device.

In this embodiment, since the plurality of electrodes 4 are arranged on the top surface of the semiconductor carrier 6 at different pitches, this can increase the degree of flexibility in arranging the plurality of electrodes 4, and allows, for example, the capacitance of an ESD protection circuit for an analog circuit, etc., to greatly vary. This capacitance variation can improve resistance to a surge breakdown.

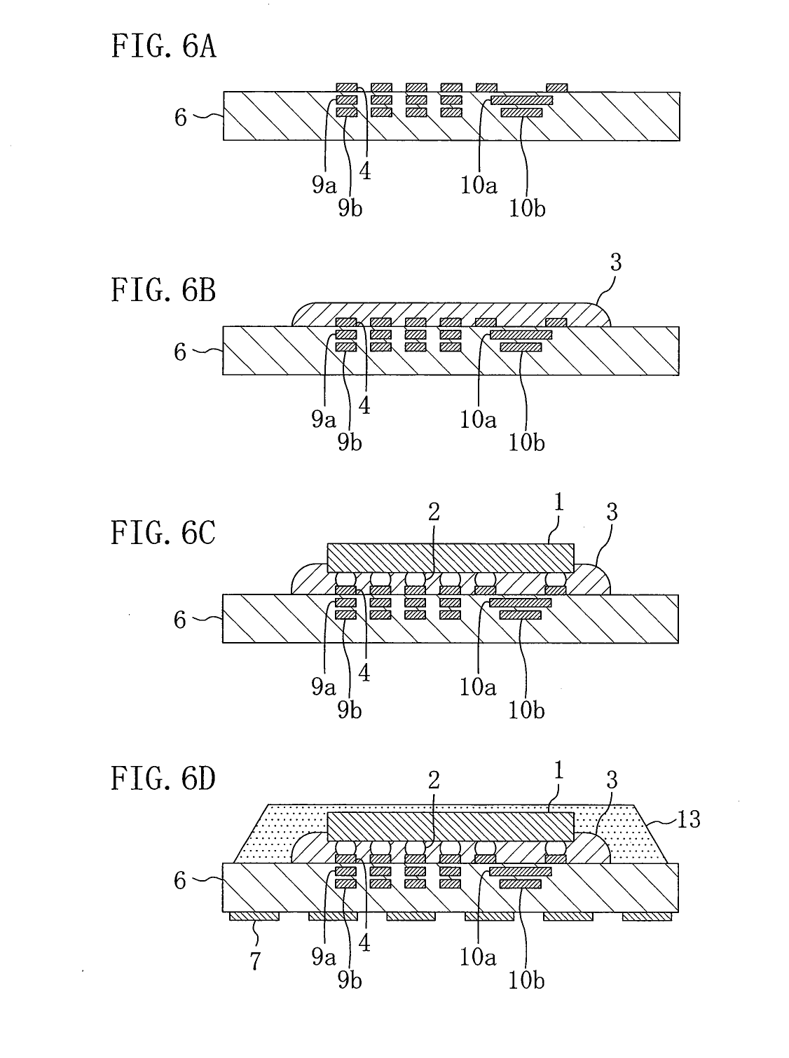

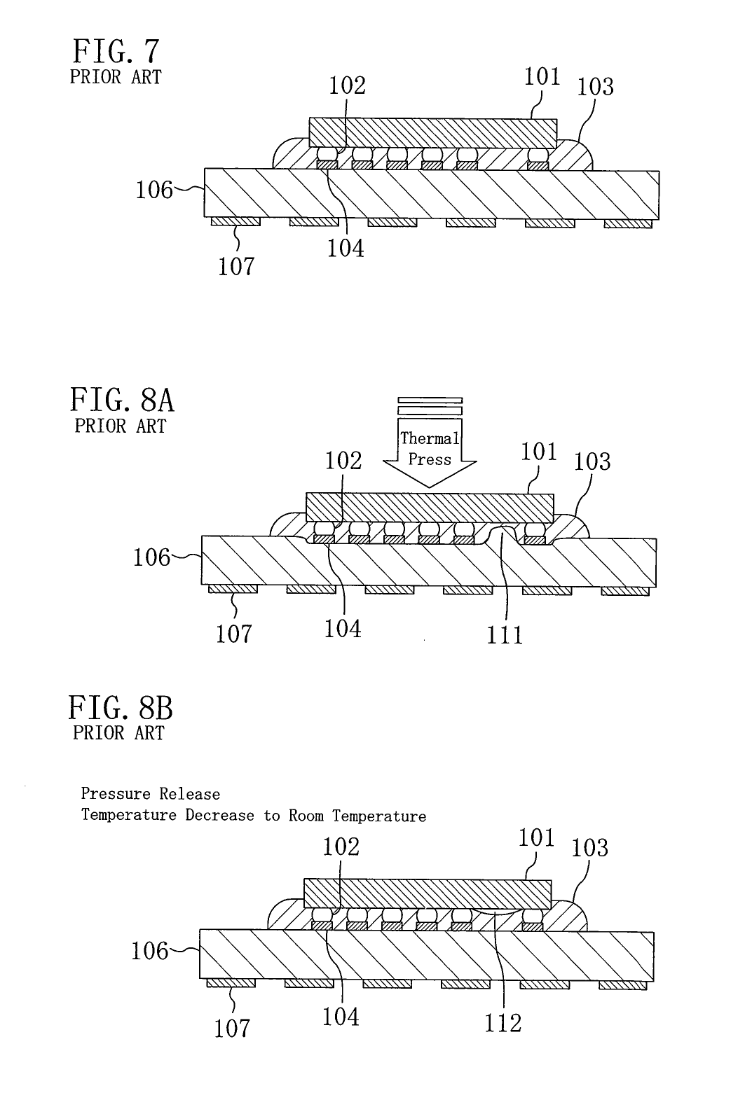

FIGS. 6A through 6D are cross-sectional views illustrating process steps in the fabrication method for a semiconductor device according to the third embodiment of the present disclosure. Referring to FIGS. 6A through 6D, the same components as those of the semiconductor device of this embodiment illustrated in FIG. 5 are labeled with the same reference characters, and redundant discussion thereof is omitted.

First, as illustrated in FIG. 6A, a semiconductor carrier 6 is prepared. A plurality of electrodes 4 are disposed on the top surface of the semiconductor carrier 6, and conductive patterns 9a, 9b, 10a, and 10b are buried in the semiconductor carrier 6. Then, as illustrated in FIG. 6B, a resin sheet forming an insulative resin 3 is disposed on the top surface of the semiconductor carrier 6 to cover the electrodes 4.

Subsequently, as illustrated in FIG. 6C, a semiconductor element 1 is electrically connected through a plurality of conductive bump electrodes 2 to the plurality of electrodes 4 disposed on the top surface of the semiconductor carrier 6 so that the bump electrodes 2 break through the resin sheet forming the insulative resin 3. Thereafter, as illustrated in FIG. 6D, the semiconductor element 1 mounted face-down on the top surface of the semiconductor carrier 6 is covered with an insulative resin 13, e.g., a thermosetting resin, and a plurality of external electrodes 7 are formed on the bottom surface of the semiconductor carrier 6.

In this embodiment, before the electrodes 4 are connected to the bump electrodes 2 in the process step illustrated in FIG. 6C, the electrodes 4 are covered with the resin sheet forming the insulative resin 3 in the process step illustrated in FIG. 6B. Alternatively, the process step illustrated in FIG. 6B may be omitted. In this case, a space between the semiconductor element 1 and the semiconductor carrier 6 may be filled with the insulative resin 13 in the process step illustrated in FIG. 6D.

What is claimed is:

1. A semiconductor device comprising:
a semiconductor carrier with a top surface on which a plurality of electrodes are disposed; and
a semiconductor element electrically connected through a plurality of bump electrodes to the plurality of associated electrodes,
wherein the plurality of electrodes are substantially uniformly spaced.

2. The semiconductor device of claim 1, wherein
the plurality of electrodes include a first electrode having a first width, and a second electrode having a second width greater than the first width.

3. The semiconductor device of claim 2, wherein
a middle of the second electrode is separated from a middle of one of the plurality of bump electrodes connected to the second electrode.

4. The semiconductor device of claim 2, wherein
a middle of the second electrode coincides with a middle of one of the plurality of bump electrodes connected to the second electrode.

5. A semiconductor device comprising:
a semiconductor carrier with a top surface on which a plurality of electrodes are disposed; and
a semiconductor element electrically connected through a plurality of bump electrodes to the plurality of associated electrodes,
wherein spacing intervals between adjacent ones of the plurality of electrodes include a first spacing interval and a second spacing interval greater than the first spacing interval, and
a dummy electrode is disposed on the top surface of the semiconductor carrier and between an adjacent pair of the plurality of electrodes spaced at the second spacing interval.

6. The semiconductor device of claim 5, wherein
the plurality of electrodes and the dummy electrode are uniformly spaced.

7. The semiconductor device of claim 5, wherein
middles of the plurality of electrodes coincide with middles of the plurality of associated bump electrodes.

8. A semiconductor device comprising:
a semiconductor carrier with a top surface on which a plurality of electrodes are disposed; and
a semiconductor element electrically connected through a plurality of bump electrodes to the plurality of associated electrodes,
wherein a conductive pattern is buried in a part of the semiconductor carrier located under at least one of the plurality of electrodes.

9. The semiconductor device of claim 8, wherein
a conductive pattern is buried in a part of the semiconductor carrier located between at least one adjacent pair of the plurality of electrodes.

10. A semiconductor device comprising:
a semiconductor carrier with a top surface on which a plurality of electrodes are disposed; and
a semiconductor element electrically connected through a plurality of bump electrodes to the plurality of associated electrodes,
wherein a conductive pattern is buried in a part of the semiconductor carrier located between at least one adjacent pair of the plurality of electrodes.

11. The semiconductor device of claim 10, wherein
an interval between the adjacent pair of the plurality of electrodes is greater than each of intervals between the other adjacent pairs of the plurality of electrodes.

12. The semiconductor device of claim 8, wherein
the conductive pattern is buried in a part of the semiconductor carrier located under the semiconductor element.

13. The semiconductor device of claim 1, wherein
the semiconductor element is mounted face-down on the top surface of the semiconductor carrier, and is covered with a resin.

14. The semiconductor device of claim 13, wherein
the resin is a thermosetting resin.

15. The semiconductor device of claim 1, wherein
a space between the semiconductor element and the semiconductor carrier is filled with an insulative resin.

16. The semiconductor device of claim 1, wherein
the plurality of electrodes are arranged at least two different pitches.
